(19) United States
(12) Patent Application Publication
(10) Pub. No.: US 2025/0140724 A1
(43) Pub. Date: May 1, 2025

(54) Multiple Polymer Layers as the Encapsulant of Conductive Vias

(71) Applicant: Taiwan Semiconductor Manufacturing Co., Ltd., Hsinchu (TW)

(72) Inventors: Meng-Che Tu, Hsinchu (TW); Po-Nan Yeh, Hsinchu (TW); Po-Han Wang, Hsinchu (TW); Yu-Hsiang Hu, Hsinchu (TW); Hung-Jui Kuo, Hsinchu (TW)

(21) Appl. No.: 18/420,595

(22) Filed: Jan. 23, 2024

Related U.S. Application Data
(60) Provisional application No. 63/592,971, filed on Oct. 25, 2023.

(51) Int. Cl. H01L 23/00; H01L 23/31

(52) U.S. Cl. CPC H01L 24/11; H01L 23/3107; H01L 24/03; H01L 24/13; H01L 2224/02181; H01L 2224/10125; H01L 2224/11013

(57) ABSTRACT

A method includes forming a conductive pillar over and connecting to a conductive pad, dispensing a first polymer layer, wherein the first polymer layer contacts a lower portion of a sidewall of the conductive pillar, curing the first polymer layer, and dispensing a second polymer layer on the first polymer layer. The second polymer layer contacts an upper portion of the sidewall of the conductive pillar. The second polymer layer is then cured.

### PRIORITY CLAIM AND CROSS-REFERENCE

This application claims the benefit of the following provisionally filed U.S. Patent application: Application No. 63/592,971, filed on Oct. 25, 2023, and entitled “INFO TD STRUCTURE,” which application is hereby incorporated herein by reference.

### BACKGROUND

In the formation of integrated circuits, integrated circuit devices such as transistors are formed at the surface of a semiconductor substrate in a wafer. An interconnect structure is then formed over the integrated circuit devices. A metal pad is formed over, and is electrically coupled to, the interconnect structure. A passivation layer and a first polymer layer are formed over the metal pad, with the metal pad exposed through an opening in the passivation layer and the first polymer layer. The first polymer layer has the function of buffering stress.

A metal pillar may then be formed to connect to the top surface of the metal pad, followed by the formation of a second polymer layer over the redistribution line.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 8 illustrate the cross-sectional views of intermediate stages in the formation of a device die in accordance with some embodiments.

FIGS. 9 through 16 illustrate the cross-sectional views of intermediate stages in the formation of a package including a device die in accordance with some embodiments.

FIG. 17 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated circuit package and the method of forming the same are provided. In accordance with some embodiments of the present disclosure, a device die is formed, which includes a metal via (also referred to as a metal pillar or a metal bump). A first polymer layer is dispensed and cured. The first polymer layer contacts the sidewalls of a lower portion of the metal via. A second polymer layer is then dispensed on, and contacts, the first polymer layer. The second polymer layer may be in contact with the sidewalls of an upper portion of the metal via. By forming multiple polymer layers, the delamination between the polymer layer and the underlying feature such as a passivation layer is eliminated.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

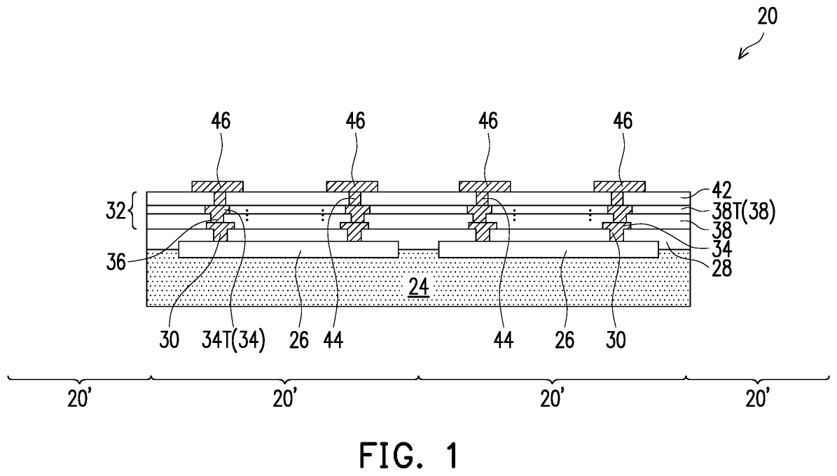

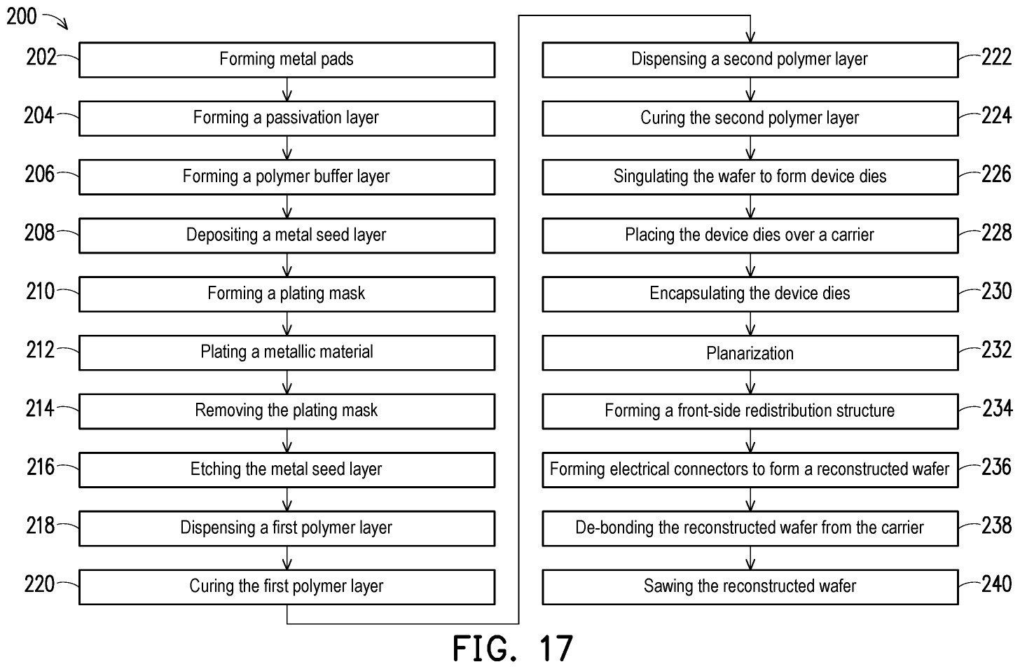

FIGS. 1 through 16 illustrate the cross-sectional views of intermediate stages in the formation of a package in accordance with some embodiments of the present disclosure. The corresponding processes are also reflected schematically in the process flow shown in FIG. 17.

FIG. 1 illustrates a cross-sectional view of (integrated circuit) device 20. In accordance with some embodiments of the present disclosure, device 20 is or comprises a device wafer including active devices and possibly passive devices, which are represented as integrated circuit devices 26. Device 20 may include a plurality of chips (device dies) 20′ therein, with one of dies 20′ being illustrated. In accordance with alternative embodiments of the present disclosure, device 20 is an interposer wafer, which is free from active devices, and may or may not include passive devices. In accordance with yet alternative embodiments of the present disclosure, device 20 is or comprises a package substrate strip, which includes a core-less package substrate or a cored package substrate with a core therein. In subsequent discussion, a device wafer is used as an example of device 20, and device 20 may also be referred to as wafer 20. The embodiments of the present disclosure may also be applied on interposer wafers, package substrates, packages, etc.

In accordance with some embodiments of the present disclosure, wafer 20 includes semiconductor substrate 24 and the features formed at a top surface of semiconductor substrate 24. Semiconductor substrate 24 may be formed of or comprise crystalline silicon, crystalline germanium, silicon germanium, carbon-doped silicon, or a III-V compound semiconductor such as GaAsP, AlInAs, AlGaAs, GaInAs, GaInP, GaInAsP, or the like. Shallow Trench Isolation (STI) regions (not shown) may be formed in semiconductor substrate 24 to isolate the active regions in semiconductor substrate 24.

In accordance with some embodiments of the present disclosure, wafer 20 includes integrated circuit devices 26, which are formed on the top surface of semiconductor substrate 24. Integrated circuit devices 26 may include Complementary Metal-Oxide Semiconductor (CMOS) transistors, resistors, capacitors, diodes, and the like in accordance with some embodiments. The details of integrated circuit devices 26 are not illustrated herein. In accordance with alternative embodiments, wafer 20 is used for forming interposers (which are free from active devices).

Inter-Layer Dielectric (ILD) 28 is formed over semiconductor substrate 24 and fills the spaces between the gate stacks of transistors (not shown) in integrated circuit devices 26. In accordance with some embodiments, ILD 28 is formed of silicon oxide, Phospho Silicate Glass (PSG), Boro Silicate Glass (BSG), Boron-doped Phospho Silicate Glass (BPSG), Fluorine-doped Silicate Glass (FSG), or the like. ILD 28 may be formed using spin-on coating, Flowable Chemical Vapor Deposition (FCVD), or the like. In accordance with some embodiments of the present disclosure, ILD 28 may also be formed using a deposition method such as Plasma Enhanced Chemical Vapor Deposition (PECVD), Low Pressure Chemical Vapor Deposition (LPCVD), or the like.

Contact plugs 30 are formed in ILD 28, and are used to electrically connect integrated circuit devices 26 to overlying metal lines and vias. In accordance with some embodiments of the present disclosure, contact plugs 30 are formed of or comprise a conductive material selected from tungsten, aluminum, copper, titanium, tantalum, titanium nitride, tantalum nitride, alloys therefore, and/or multi-layers thereof. The formation of contact plugs 30 may include forming contact openings in ILD 28, filling a conductive material(s) into the contact openings, and performing a planarization process (such as a Chemical Mechanical Polish (CMP) process or a mechanical grinding process) to level the top surfaces of contact plugs 30 with the top surface of ILD 28.

Interconnect structure 32 is formed over integrated circuit devices 26. Interconnect structure 32 includes metal lines 34 and vias 36, which are formed in dielectric layers 38 (also referred to as Inter-metal Dielectrics (IMDs)) and etch stop layers (not shown). The metal lines at a same level are collectively referred to as a metal layer hereinafter. In accordance with some embodiments of the present disclosure, interconnect structure 32 includes a plurality of metal layers including metal lines 34 that are interconnected through vias 36. Metal lines 34 and vias 36 may be formed of copper or copper alloys, and can also be formed of other metals.

In accordance with some embodiments of the present disclosure, dielectric layers 38 are formed of low-k dielectric materials. The dielectric constants (k values) of the low-k dielectric materials may be lower than about 3.5, for example. Dielectric layers 38 may comprise a carbon-containing low-k dielectric material, Hydrogen SilsesQuioxane (HSQ), MethylSilsesQuioxane (MSQ), or the like. The etch stop layers are formed underlying the respective dielectric layers 38, and may be formed of or comprise aluminum nitride, aluminum oxide, silicon oxycarbide, silicon nitride, silicon carbide, silicon oxynitride, or the like, or multi-layers thereof.

The formation of metal lines 34 and vias 36 may include single damascene processes and/or dual damascene processes. In a single damascene process for forming a metal line or a via, a trench or a via opening is first formed in one of dielectric layers 38, followed by filling the trench or the via opening with a conductive material. A planarization process such as a CMP process is then performed to remove the excess portions of the conductive material higher than the top surface of the dielectric layer, leaving a metal line or a via in the corresponding trench or via opening. In a dual damascene process, both of a trench and a via opening are formed in a dielectric layer, with the via opening underlying and connected to the trench. Conductive materials are then filled into the trench and the via opening to form a metal line and a via, respectively. The conductive materials may include a diffusion barrier layer and a copper-containing metallic material over the diffusion barrier layer. The diffusion barrier layer may include titanium, titanium nitride, tantalum, tantalum nitride, or the like.

Metal lines 34 include top conductive (metal) features (denoted as 34T) such as metal lines, metal pads, or vias in a top dielectric layer (denoted as dielectric layer 38T), which is the top layer of dielectric layers 38. In accordance with some embodiments, dielectric layer 38T is formed of a low-k dielectric material similar to the material of lower ones of dielectric layers 38. The metal features 34T in the top dielectric layer 38T may also be formed of copper or a copper alloy, and may have a dual damascene structure or a single damascene structure.

In accordance with some embodiments, an etch stop layer (not shown) may be deposited on the top dielectric layer 38T and the top metal layer. The etch stop layer may be formed of or comprise silicon nitride, silicon oxide, silicon oxycarbide, silicon oxynitride, or the like.

Passivation layer 42 (sometimes referred to as passivation-1 or pass-1) may be formed over the metal features 34T and the top dielectric layer 38T. In accordance with some embodiments, passivation layer 42 is formed of a non-low-k dielectric material having a dielectric constant equal to or greater than the dielectric constant of silicon oxide. Passivation layer 42 may be formed of or comprise an inorganic dielectric material, which may include a material selected from, and is not limited to, Undoped Silicate Glass (USG), silicon nitride (SiN), silicon oxide (SiO₂), silicon oxy-nitride (SiON), silicon oxy-carbide (SiOC), or the like, combinations thereof, and/or multi-layers thereof. In accordance with some embodiments, the top surfaces of top dielectric layer 38T and metal lines 34T are level with one another. Accordingly, passivation layer 42 may be a planar layer.

In accordance with some embodiments, vias 44 are formed in passivation layer 42 to electrically connect to the underlying top metal features 34T. Metal pads 46 are further formed over vias 44. The corresponding process is shown as process 202 in the process flow 200 as shown in FIG. 17. In accordance with some embodiments, metal pads 46 comprise aluminum, aluminum copper, copper, or the like.

In accordance with some embodiments, vias 44 and metal pads 46 are formed in a same process. The formation process may include etching passivation layer 42 to form openings, depositing a metal layer including first portions extending into the openings and second portions over the passivation layer 42, and patterning the metal layer to form vias 44 and metal pads 46. In accordance alternative embodiments, the formation process may include depositing a metal seed layer, forming a patterned plating mask, and plating a metal layer over the metal seed layer and extending into the openings. The patterned plating mask is then removed, followed by etching the portions of the metal seed layer previously covered by the plating mask. In accordance with yet alternative embodiments, vias 44 and metal pads 46 are formed separately, with vias 44 being formed in a single damascene process, and metal pads 46 being formed through deposition and patterning.

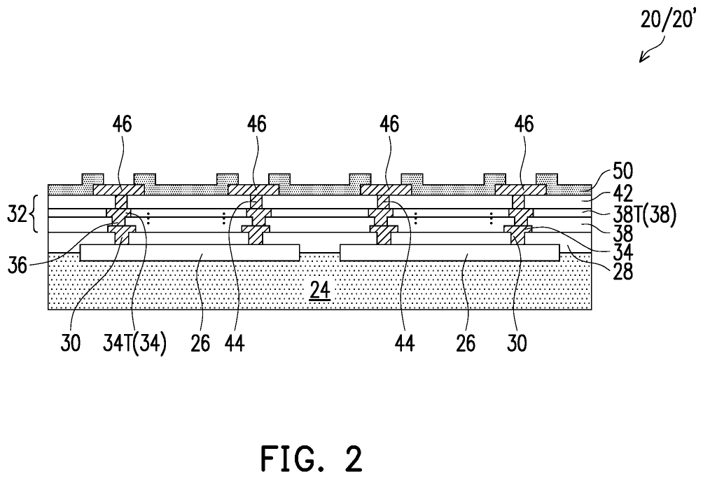

Next, as also shown in FIG. 2, passivation layer 50 (sometimes referred to as passivation-2 or pass-2) is formed. The corresponding process is shown as process 204 in the process flow 200 as shown in FIG. 17. In accordance with some embodiments, passivation layer 50 is formed of or comprises an inorganic dielectric material, which may include a nitride-based dielectric material such as silicon nitride, silicon oxynitride, silicon carbo-nitride, or the like. In accordance with alternative embodiments, passivation layer 50 may include an oxide-based dielectric material such as Undoped Silicate Glass (USG), Spin-On Glass (SOG), silicon oxide, or the like.

In accordance with yet alternative embodiments, passivation layer 50 may have a multi-layer structure including a plurality of layers. For example, passivation layer 50 may include a silicon nitride layer, and a silicon oxide layer over the silicon nitride layer. There may be, or may not be, an additional silicon nitride layer over the silicon oxide layer. Passivation layer 50 and the sub layers (if any) in passivation layer 50 may be formed through a conformal deposition process such as Atomic Layer Deposition (ALD), Chemical Vapor Deposition (CVD), or the like.

In accordance with yet alternative embodiments, passivation layer 50 is formed of an organic dielectric material such as a polymer, which is dispensed in a flowable form, and is then cured as a solid. In accordance with these embodiments, passivation layer 50 may be formed of a photo-sensitive polymer (such as polyimide, polybenzoxazole (PBO), benzocyclobutene (BCB), or the like.) or a non-photo-sensitive polymer.

After the deposition of passivation layer 50, a patterning process may be performed through an anisotropic etching process, so that via openings are formed in passivation layer 50, with the underlying metal pad 46 being exposed. The patterning process may include forming a photoresist layer, and performing a light-exposure process and a development process on the photoresist layer. The undesirable portions of the photoresist layer are thus removed, and the patterned photoresist layer is used as an etching mask to etching passivation layer 50, so that openings are formed in passivation layer 50. After the patterning of the passivation layer 50, the etching mask is removed.

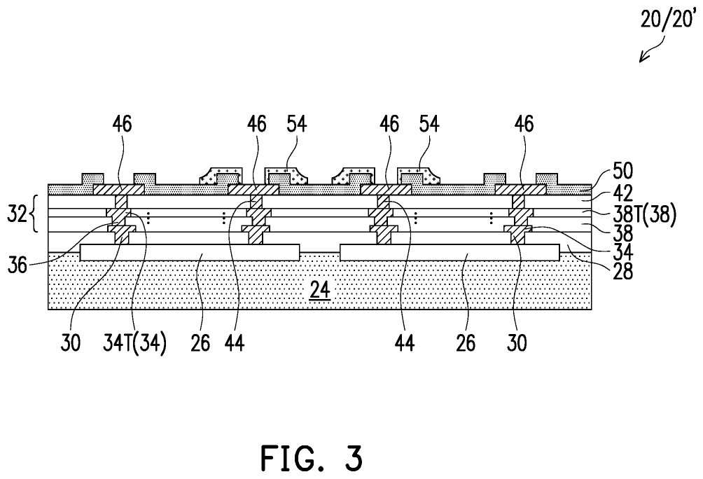

Referring to FIG. 3, polymer buffer layer 54 is selectively formed on some, but not all of metal pads 46. The corresponding process is shown as process 206 in the process flow 200 as shown in FIG. 17. In accordance with some embodiments, polymer buffer layer 54 may be formed of a polymer. The polymer may be photo-sensitive or non-photo-sensitive. Polymer buffer layer 54 may formed through a dispensing process, for example, through spin-on coating. Polymer buffer layer 54 may comprise polyimide, PBO, BCB, or the like. After the dispensing, polymer buffer layer 54 is patterned. In accordance with some embodiments, the thickness of polymer buffer layer 54 may be in the range between about 3 μm and about 8 μm.

In accordance with some embodiments in which polymer buffer layer 54 is photo-sensitive, the patterning may include, after the dispensing, baking polymer buffer layer 54, performing a light-exposure process (using a lithography mask), and developing the exposed polymer buffer layer 54, so that undesirable portions of the polymer buffer layer 54 are removed. A post-baking process may then be performed, so that polymer buffer layer 54 is cross-linked and is not further patterned by subsequent light-exposure and development process.

In accordance with alternative embodiments in which polymer buffer layer 54 is not photo-sensitive, the formation of polymer buffer layer 54 may include dispensing polymer buffer layer 54, and curing polymer buffer layer 54 as a solid. An etching mask such as a photoresist layer may then be formed over polymer buffer layer 54, followed by etching polymer buffer layer 54 using the photoresist layer as an etching mask. The etching mask is then removed.

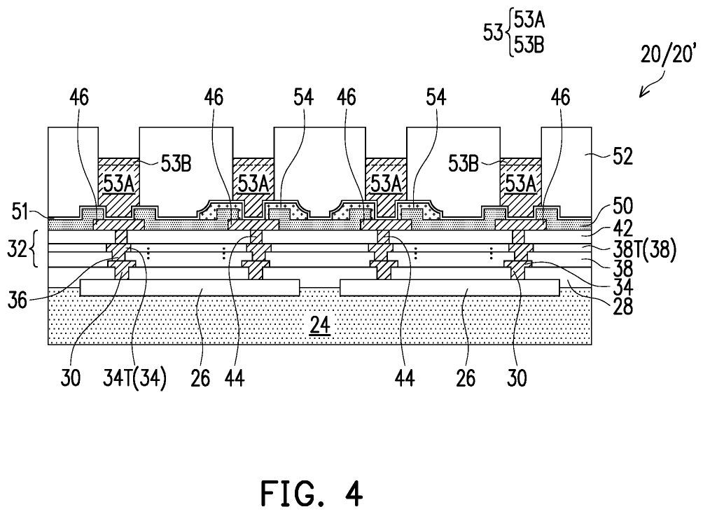

Next, referring to FIG. 4, a metal seed layer 51 is formed, for example, deposited through Physical Vapor Deposition (PVD) in accordance with some embodiments. The corresponding process is shown as process 208 in the process flow 200 as shown in FIG. 17. The metal seed layer may comprise a titanium layer, and a copper layer over the titanium layer.

Further referring to FIG. 4, plating mask 52 is formed on the metal seed layer 51, and is patterned, with openings formed to overlap metal pads 46. The corresponding process is shown as process 210 in the process flow 200 as shown in FIG. 17. A metallic material 56 is then plated. The corresponding process is shown as process 212 in the process flow 200 as shown in FIG. 17. In accordance with some embodiments, the deposition is performed through electrochemical plating. The metallic material may comprise copper, nickel, tungsten, cobalt, or the like, combinations thereof, and/or multi-layers thereof.

In accordance with some embodiments, the entire plated metallic material 53 is formed of a homogeneous material such as copper, tungsten, cobalt, or the like. In accordance with alternatively embodiments, the plated material metallic 53 comprises a lower layer (such as a copper layer) 53A and an upper layer (such as a nickel layer or a solder layer) 53B over the lower layer.

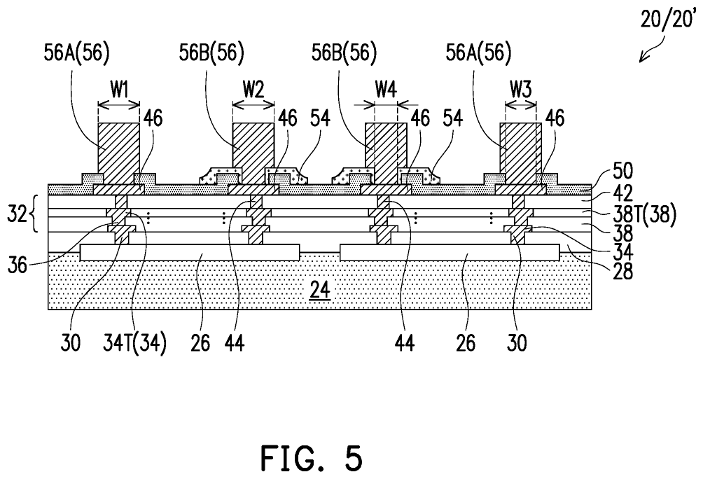

Plating mask 52 is then removed. The corresponding process is shown as process 214 in the process flow 200 as shown in FIG. 17. Some portions of the metal seed layer 51 are exposed. The exposed portions of the metal seed layer 51 are then removed through etching, with the metallic material being used as an etching mask. The corresponding process is shown as process 216 in the process flow 200 as shown in FIG. 17. The remaining portions of the metal seed layer 51 and the plated metallic material 53 are collectively referred to as metal vias (or metal pillars and metal bumps) 56, as shown in FIG. 5. In accordance with some embodiments, metal vias 56 have vertical or substantially vertical sidewalls, for example, with tilt angles being in the range between about 87 degrees and about 93 degrees.

Due to the selective formation of polymer buffer layer 54 on some of metal pads 46, polymer buffer layer 54 is selectively formed under some metal vias 56 (such as larger metal vias 56), but not under other metal vias 56 (such as narrower metal vias 56). For example, metal vias 56 may include metal vias 56A and 56B. The width (or length) W2 of via 56B may be greater than width W1 of via 56A. The ratio W2/W1 may be greater than about 1.2, and may be in the range between about 1.2 and about 5. In FIG. 5, dashed lines are used to represent the possible positions of the edges of vias 56B when they are narrower than vias 56A.

In accordance with alternative embodiments, width W2 of vias 56B may be equal to or greater than the width W1 of via 56A. In accordance with some embodiments, width W1 may be in the range between about 10 μm and about 20 μm, and width W2 may be in the range between about 24 μm and about 60 μm. The immediately neighboring polymer buffer layer 54 that are separated from each other may have spacings smaller than about 200 μm.

Also, the openings of the portion of metal vias 56A and 56B in passivation layer 50 may have widths W3 and W4, respectively, with width W4 being greater than width W3. The ratio W4/W3 may be greater than about 1.2, and may be in the range between about 1.2 and about 5. In accordance with some embodiments, width W3 may be in the range between about 6 μm and about 12 μm, and width W4 may be in the range between about 10 μm and about 35 μm. The height of the narrower via 56A may be greater than the height of the wider via 56B.

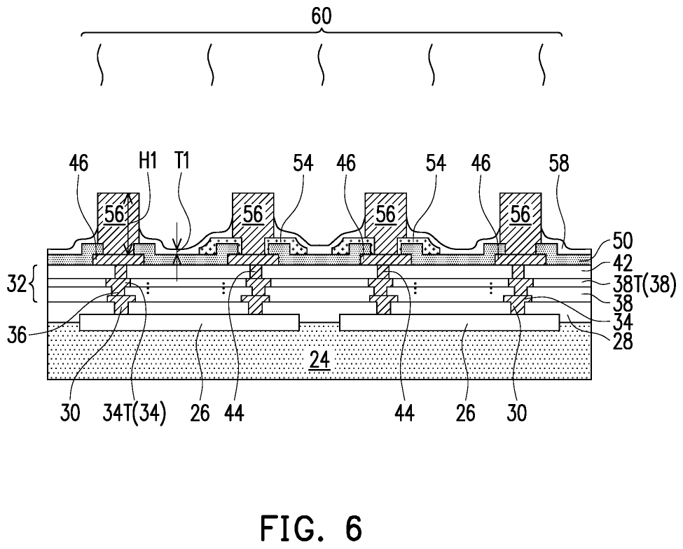

Referring to FIG. 6, polymer layer 58 is dispensed. The corresponding process is shown as process 218 in the process flow 200 as shown in FIG. 17. In accordance with some embodiments, polymer layer 58 comprises a polymer, which is dispensed in a flowable form. polymer layer 58 may comprise polyimide, PBO, BCB, or the like. The dispensing may comprise spin-on coating. The amount of polymer layer 58 is controlled, so that when the spin-on coating is finished, polymer layer 58 is a thin layer that covers passivation layer 50. In accordance with some embodiments, the entire exposed surface of passivation layer 50 is covered.

Polymer layer 58 contacts the lower portions of the sidewalls of metal vias 56, while the upper portions of the sidewalls and the top surfaces of metal vias 56 are exposed. In accordance with some embodiments, no light-exposure process is performed on polymer layer 58, and no development process is performed on polymer layer 58. The selective formation of polymer layer 58 on the lower portions of the sidewalls of metal vias 56 is due to the spin-on coating and the controlling of the amount of polymer layer 58. In accordance with some embodiments, the thickness T1 of polymer layer 58 may be in the range between about 3 percent and about ⅔ of the height H1 of metal vias 56. In accordance with some embodiments, thickness T1 is smaller than about 15 μm, and may be in the range between about 1 μm and about 15 μm.

Polymer layer 58 is cured in curing process 60, and thus is solidified. The corresponding process is shown as process 220 in the process flow 200 as shown in FIG. 17. In accordance with some embodiments, the curing process 60 comprises a soft bake process, while no hard bake process is included in curing process 60. In accordance with some embodiments, the soft bake process is performed at a temperature in a first temperature range between about 90° C. and about 110° C. The duration of the soft bake process may be in the range between about 1 minute and about 5 minutes. The solvent in polymer layer 58 is driven out by the soft bake process.

In accordance with some embodiments, after the soft bake process, no hard bake process is performed, and process proceeds to the dispensing of polymer layer 62. In accordance with alternative embodiments, after the soft bake process, a hard bake process is performed at a second temperature higher than the first temperature used for the soft bake process. For example, the second temperature may be in the range between about 140° C. and about 250° C. The duration of the hard bake process may be in the range between about 5 minute and about 1 hour.

In accordance with some embodiments, the curing process 60 results in the full solidification of polymer layer 58. In accordance with alternative embodiments, the curing process 60 results in the partial solidification of polymer layer 58, wherein the cured polymer layer 58 is solid, but is softer than if a hard bake process is performed. Alternatively, the partially cured polymer layer 58 may also be considered as being flowable, but is less flowable than when it is dispensed. A parameter “imidization ratio” may be used to measure the degree of curing. The higher the imidization ratio, the higher the mechanical strength the polymer material will have, and the corresponding polymer layer 58 is harder. Accordingly, the partially cured polymer layer 58 has a first imidization ratio lower than a second imidization ratio after it is fully cured (such as after the hard bake process).

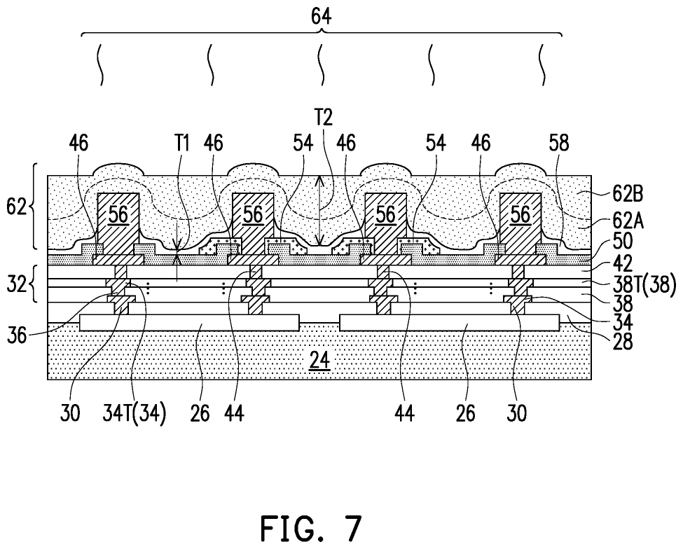

Referring to FIG. 7, polymer layer 62 is dispensed. The corresponding process is shown as process 222 in the process flow 200 as shown in FIG. 17. In accordance with some embodiments, polymer layer 62 comprises a polymer, which is dispensed in a flowable form. For example, polymer layer 62 may comprise polyimide, PBO, BCB, or the like. The material of polymer layer 62 may be the same as or different from the material of polymer buffer layer 54. The dispensing may comprise spin-on coating. In accordance with some embodiments, polymer layer 62 fully fills the gaps between neighboring metal vias 56, with metal vias 56 being covered by polymer layer 62. The overlapping portions may have a thickness greater than about 3 μm.

Polymer layer 62 contacts the top surfaces and the upper portions of the sidewalls of metal vias 56, In accordance with some embodiments, the thickness T2 of polymer layer 62 is greater than the thickness T1 of polymer layer 58. In accordance with some embodiments, thickness T2 is greater than about 10 μm, and may be in the range between about 10 μm and about 50 μm. In accordance with some embodiments, no light-exposure process and no development process are performed on polymer layer 62.

Polymer layer 62 is cured in curing process 64. The corresponding process is shown as process 224 in the process flow 200 as shown in FIG. 17. In accordance with some embodiments, the curing process 64 comprises a soft bake process. In accordance with some embodiments, the soft bake process is performed at a first temperature in a first temperature range between about 90° C. and about 110° C., for example. The duration of the soft bake process may be in the range between about 1 minute and about 5 minutes. The solvent in polymer layer 62 is driven out by the soft bake process.

The curing process 64 may further include a hard bake process after the soft bake process. The hard bake process is performed at a second temperature higher than the first temperature used for the soft bake process. For example, the second temperature may be in the range between about 140° C. and about 250° C. The duration of the hard bake process may be in the range between about 5 minute and about 1 hour.

In accordance with some embodiments, polymer layer 62 is a homogenous layer formed of a homogeneous polymer. In accordance with alternative embodiments, polymer layer 62 comprises a plurality of sub layers such as sub layers 62A and 62B. There may be more sub layers included in polymer layer 62. The lowest levels of the interface between the sub layers (if exist) are lower than the top surfaces of metal vias 56. For example, FIG. 7 schematically illustrates sub layers 62A and 62B, and the interface between sub layers 62A and 62B. The neighboring sub layers may be formed of the same polymer or different polymers, with the materials of the sub layers being selected from the same group of candidate materials of polymer layers 58 and 62. In addition, each of the sub layers is followed by a soft bake process before the next sub layer is dispensed. Each of the sub layers may, or may not be followed by a hard bake process before the next sub layer is dispensed.

In accordance with some embodiments, a planarization process is performed to planarize the top surface of polymer layer 62. The planar top surface of the remaining polymer layer 62 may be higher than or level with the top surfaces of metal vias 56. In accordance with alternative embodiments, no planarization process is performed.

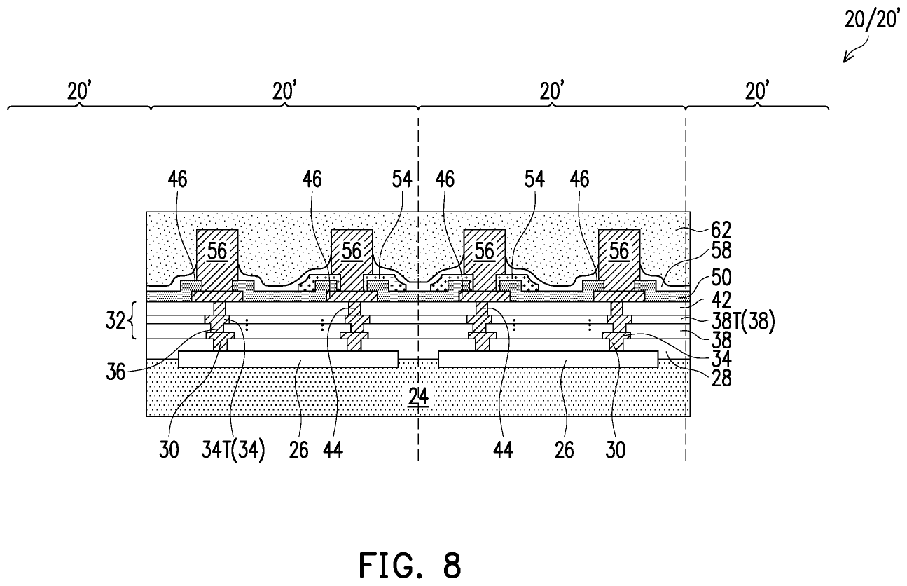

Referring to FIG. 8, wafer 20 is singulated, for example, sawed into a plurality of discrete device dies 20′. The corresponding process is shown as process 226 in the process flow 200 as shown in FIG. 17. In the sawing process, wafer 20 may be fixed on a dicing tape (not shown), which is further fixed on a frame (not shown).

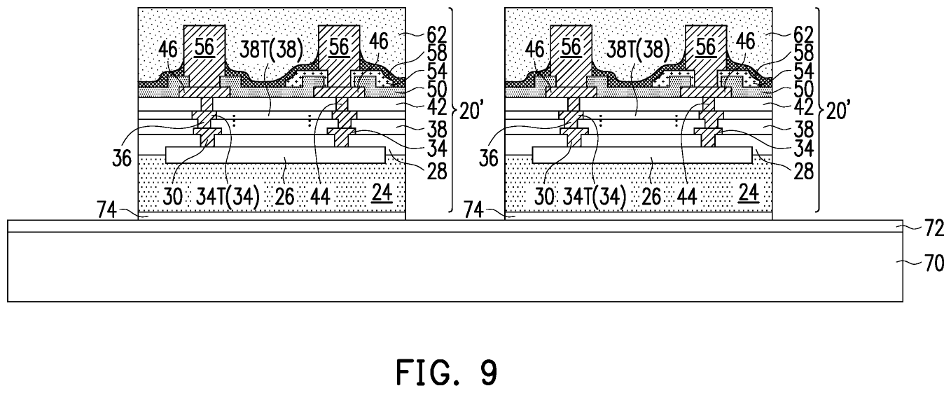

Referring to FIG. 9, carrier 70 is provided, with release film 72 being coated on carrier 70. Carrier 70 may be a glass carrier, a silicon wafer, an organic carrier, or the like. Release film 72 may be formed of a polymer-based material and/or an epoxy-based thermal-release material, such as a LTHC material.

Device dies 20′ are placed and attached to carrier 70 through die-attach films 74, which are adhesive films. The corresponding process is shown as process 228 in the process flow 200 as shown in FIG. 17. Although two device dies 20′ are shown as a group, there may be a plurality of groups of device dies 20′ attached to carrier 70.

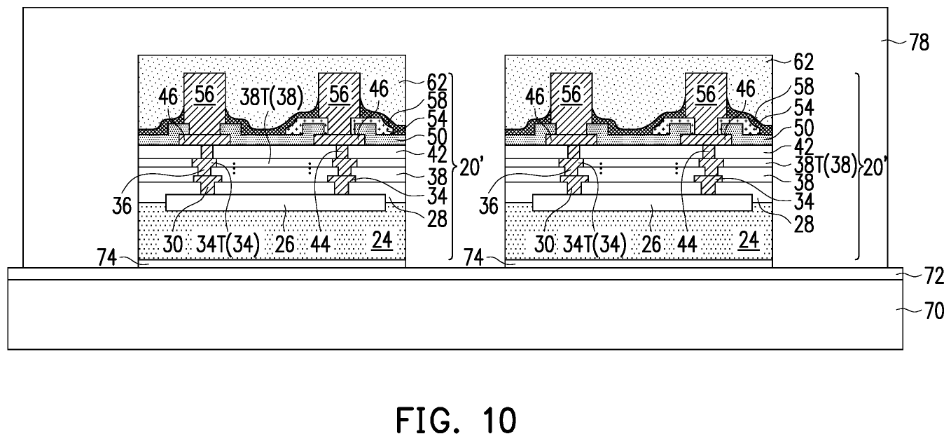

Next, device dies 20′ are encapsulated in encapsulant 78, as shown in FIG. 10. The corresponding process is shown as process 230 in the process flow 200 as shown in FIG. 17. Encapsulant 78 (also referred to as a gap-fill material) fills the gaps between neighboring device dies 20′. Encapsulant 78 may include a molding compound, a molding underfill, an epoxy, and/or a resin. Alternatively, encapsulant 78 may include inorganic dielectric layers such as a silicon nitride layer, a silicon oxide layer over the silicon nitride layer, or the like. The top surface of encapsulant 78 is higher than the top ends of metal vias 56. When a molding compound is used, the molding compound may include a base material, which may be a polymer, a resin, an epoxy, or the like, and filler particles (not shown) in the base material. The filler particles may be dielectric particles of SiO₂, Al₂O₃, silica, or the like, and may have spherical shapes. Also, the spherical filler particles may have the same or different diameters.

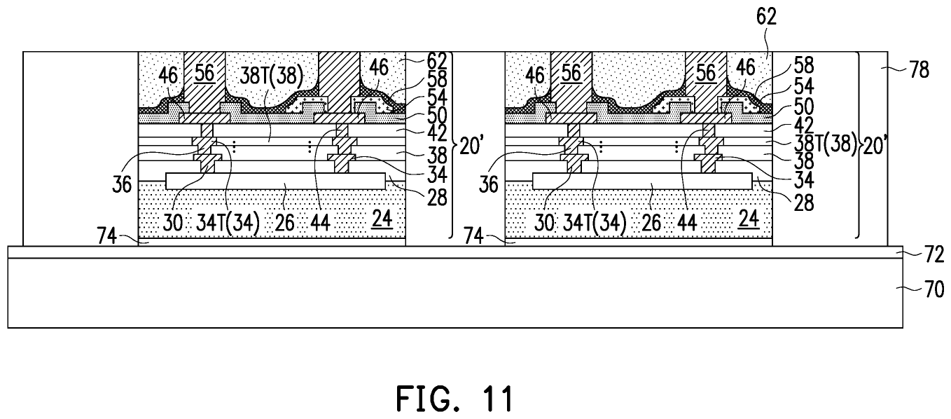

As shown in FIG. 11, a planarization process such as a CMP process or a mechanical grinding process is performed to thin encapsulant 78 and polymer layer 62, until metal vias 56 are all exposed. The corresponding process is shown as process 232 in the process flow 200 as shown in FIG. 17.

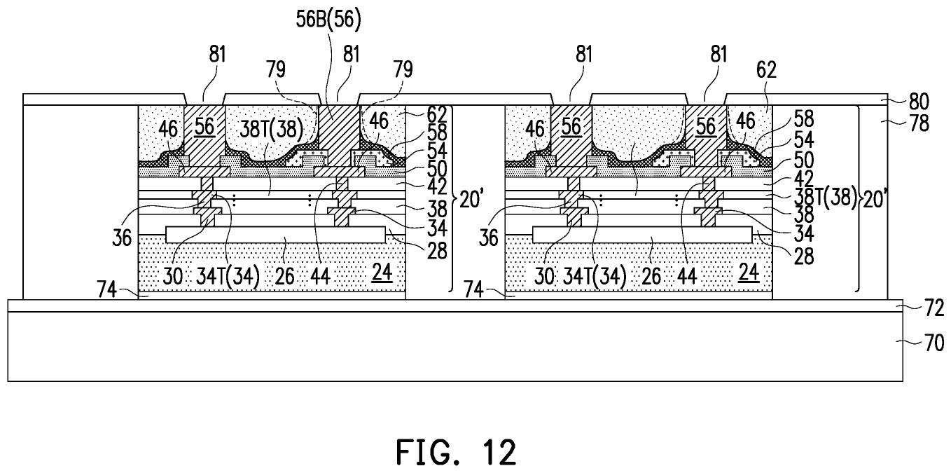

FIGS. 12 through 14 illustrate the formation of a front-side redistribution structure 86, which includes dielectric layers 80 and RDLs 82. The corresponding process is shown as process 234 in the process flow 200 as shown in FIG. 17. Referring to FIG. 12, a first dielectric layer 80 is formed. In accordance with some embodiments, dielectric layer 80 may be formed of a polymer such as PBO, polyimide, or the like. The formation of dielectric layer 80 may include coating dielectric layer 80 in a flowable form, and then curing the dielectric layer 80. In accordance with alternative embodiments of the present disclosure, dielectric layer 80 is formed of an inorganic dielectric material such as silicon nitride, silicon oxide, or the like. The formation method may include CVD, ALD, Plasma-Enhanced Chemical Vapor Deposition (PECVD), or other applicable deposition methods. Dielectric layer 80 is patterned to form openings 81, through which metal vias 56 are exposed.

In accordance with some embodiments, all of the topmost ends of polymer layer 58 are spaced apart from dielectric layer 80 by polymer layer 62. In accordance with alternative embodiments, due to process variations, some of the topmost ends of polymer layer 58 are spaced apart from dielectric layer 80, while some other topmost ends of polymer layer 58 are in contact with the bottom surface of dielectric layer 80. For example, metal vias 56B may have underlying polymer 54, which raises the height of the polymer layer 58, and hence polymer layer 58 on some or all of metal vias 56 may extend to and contact the bottom surface of dielectric layer 80. Dashed line 79 are illustrated to represent the interfaces between polymer layers 58 and 62 in accordance with these embodiments.

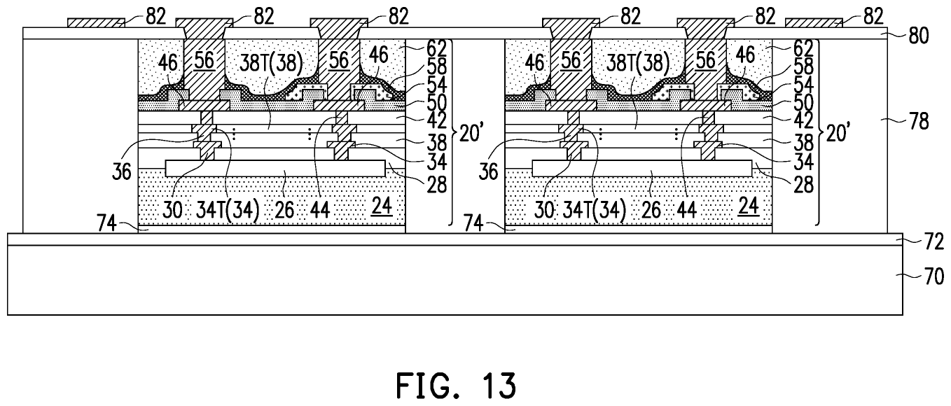

Referring to FIG. 13, RDLs 82 are formed to electrically connect to device die 20′. Each of RDLs 82 includes a via portion formed in the respective underlying dielectric layer 80, and a trace portion (metal line) over the respective dielectric layer 80. In accordance with some embodiments of the present disclosure, RDLs 82 are formed by processes including depositing a metal seed layer (not shown), forming and patterning a photoresist (not shown) over the metal seed layer, and plating a metallic material such as copper, tungsten, nickel, and/or the like over the metal seed layer. The patterned photoresist is then removed, followed by etching the portions of the metal seed layer previously covered by the patterned photoresist.

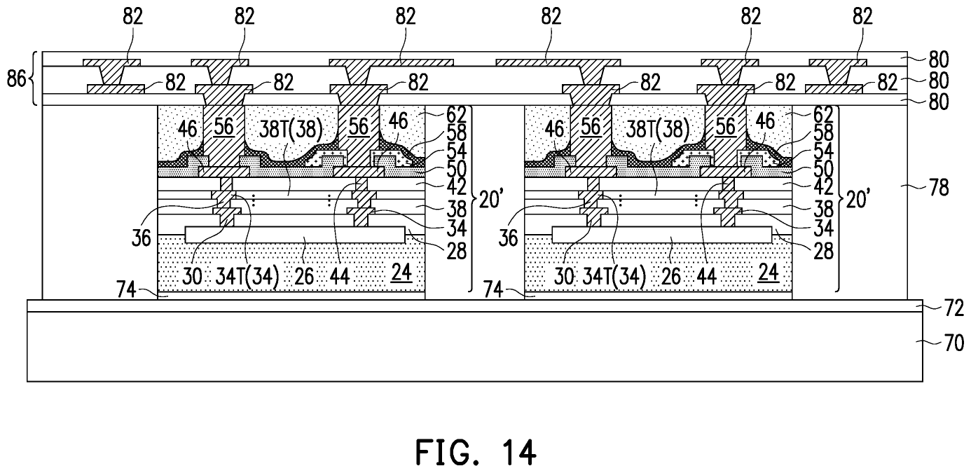

FIG. 14 illustrates the formation of more dielectric layers 80 and RDLs 82. The formation process may be similar to the formation of the dielectric layer 80 in FIG. 12 and the RDLs 82 in FIG. 13. The number of dielectric layers 80 and RDLs 82 are selected based on the routing requirements. Redistribution structure 86 is thus formed

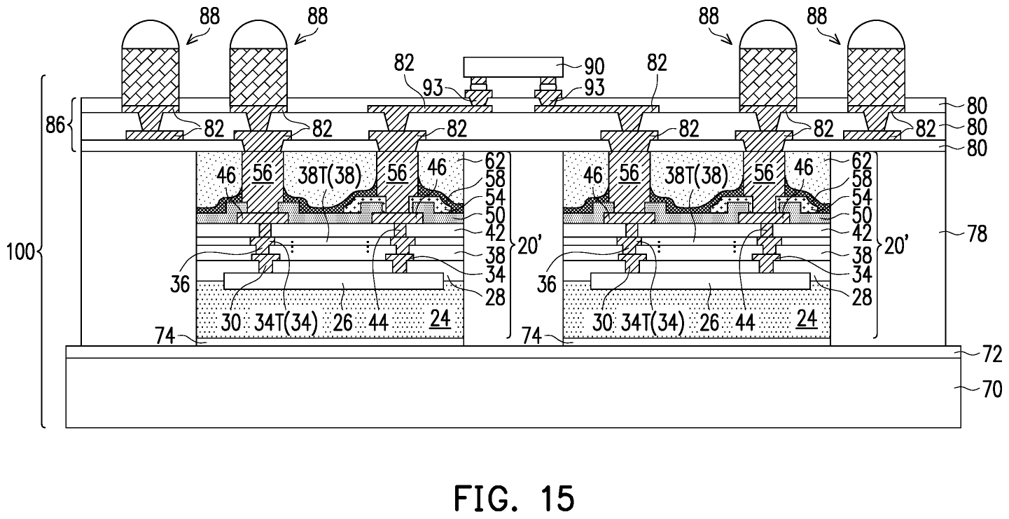

Referring to FIG. 15, electrical connectors 88 are formed. The corresponding process is shown as process 236 in the process flow 200 as shown in FIG. 17. The formation of electrical connectors 88 may include patterning a top dielectric layer 80 to form openings, placing solder balls on the exposed portions of RDLs 82, and then reflowing the solder balls. The resulting electrical connectors 88 includes solder regions. In accordance with alternative embodiments of the present disclosure, the formation of electrical connectors 88 includes performing a plating step to form solder layers over RDLs 82, and then reflowing the solder layers. Electrical connectors 88 may also include non-solder metal pillars, and there may be, or may not be, solder caps over the non-solder metal pillars. Throughout the description, the structure over release film 72 is referred to as reconstructed wafer 100.

FIG. 15 also illustrates the bonding of device 90 to redistribution structure 86. In accordance with some embodiments, device 90 includes a Local Silicon Interconnect (LSI) die, which is used a bridge die to electrically interconnect device dies 20′. Device 90 may be connected to the underlying structures through Under-Bump Metallurgies (UBMs) 93 in accordance with some embodiments.

Next, the reconstructed wafer 100 may be flipped upside down and placed on a dicing tape (not shown), which is attached to a frame (not shown). In accordance with some embodiments of the present disclosure, electrical connectors 88 are in contact with the tape. Next, reconstructed wafer 100 is de-bonded from carrier 70. The corresponding process is shown as process 238 in the process flow 200 as shown in FIG. 17. In the de-bonding process, a light beam is projected on LTHC coating material 72, and the light beam penetrates through the transparent carrier 70 to decompose the LTHC coating material 72. In accordance with some embodiments, the light beam is a laser beam, which scans through the entire LTHC coating material 72.

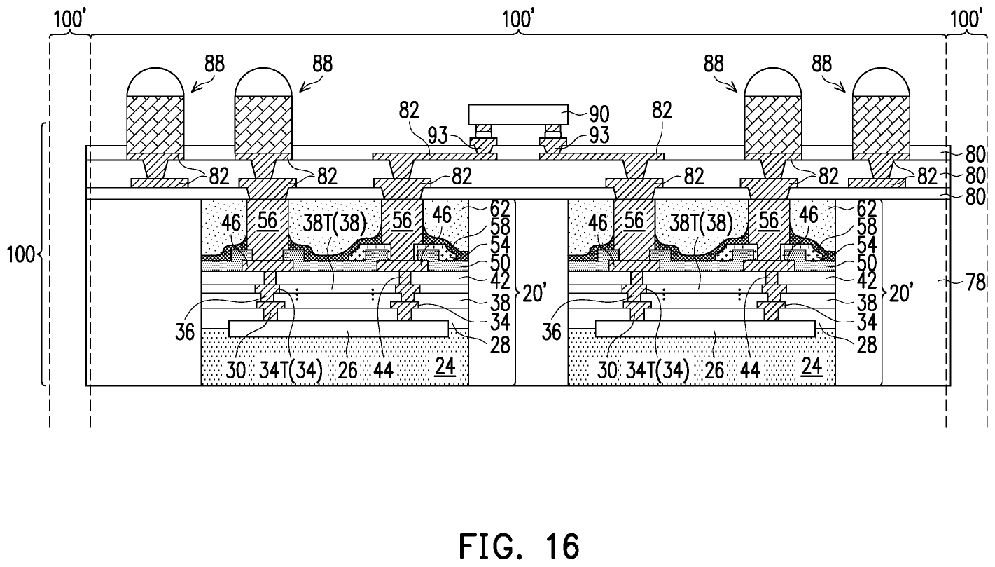

As a result of the light-exposure (such as the laser scanning), carrier 70 may be lifted off from LTHC coating material 72, and hence reconstructed wafer 100 is de-bonded (demounted) from carrier 70. The resulting reconstructed wafer 100 is shown in FIG. 16. In accordance with some embodiments, as shown in FIG. 16, dashed lines are illustrated to show the possible positions of the edges of via 56A that are narrower than vias 56B. In accordance with some embodiments, polymer buffer layer 54 extends directly underlying the wider vias 56B, but does not extend directly underlying the narrower vias 56A.

In accordance with alternative embodiments, vias 56A and 56B have the same width, and polymer buffer layer 54 still extends directly underlying some of the vias such as vias 56B, but does not extend directly underlying some other vias such as vias 56A. In accordance with yet alternative embodiments, vias 56B are wider than vias 56B, but polymer buffer layer 54 extends directly underlying vias 56A, but does not extend directly underlying vias 56A. This may occur when the wider vias 56B suffer from higher stress than narrower vias 56A, for example, when the wider vias 56B are corner vias at the corners of the respective package 100′, and the narrower vias 56A are farther away from the corners of the respective package 100′ than the wider vias 56B.

In a subsequent process, as also shown in FIG. 16, reconstructed wafer 100 is sawed apart into a plurality of packages 100′. The corresponding process is shown as process 240 in the process flow 200 as shown in FIG. 17.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. With the increasingly smaller lateral dimensions and spacings of vias, polymer is not suitable for being formed under very small vias. The lacking of the polymer, however, results in the direct contact of the encapsulating polymer to the underlying passivation layer. Experiment results have revealed that delamination occurred between the encapsulating polymer and the underlying passivation layer, and the delamination rate may reach as high as one hundred percent of the via samples. With the formation of the multiple polymer layers, the delamination is eliminated, and none of the samples has delamination found.

In accordance with some embodiments of the present disclosure, a method comprises forming a first conductive pillar over and connecting to a conductive pad; dispensing a first polymer layer, wherein the first polymer layer contacts a lower portion of a sidewall of the first conductive pillar; curing the first polymer layer; dispensing a second polymer layer on the first polymer layer, wherein the second polymer layer contacts an upper portion of the sidewall of the first conductive pillar; and curing the second polymer layer. In an embodiment, the dispensing the first polymer layer is performed through spin-on coating. In an embodiment, the first polymer layer and the second polymer layer comprise a same polymer material.

In an embodiment, the first polymer layer and the second polymer layer comprise different polymer materials. In an embodiment, the first polymer layer is fully cured before the second polymer layer is dispensed. In an embodiment, the first polymer layer is partially cured before the second polymer layer is dispensed. In an embodiment, the method further comprises, after the second polymer layer is cured, performing a planarization process to level a first top surface of the first conductive pillar with a second top surface of the second polymer layer. In an embodiment, one of the dispensing the first polymer layer and the dispensing the second polymer layer comprises dispensing polyimide.

In an embodiment, the method further comprises forming a second conductive pillar, wherein the first polymer layer extends continuously from the first conductive pillar to the second conductive pillar. In an embodiment, the method further comprises forming a passivation layer comprising a portion on the conductive pad; depositing a polymer buffer layer on the passivation layer; and patterning the polymer buffer layer to form an opening, wherein the first conductive pillar comprises a portion in the opening to contact the conductive pad.

In accordance with some embodiments of the present disclosure, a structure comprises a conductive pad; a passivation layer partially covering the conductive pad; a conductive pillar comprising a first portion in the passivation layer and in contact with the conductive pad; and a second portion over the passivation layer, wherein the second portion comprises a sidewall; a first polymer layer over the passivation layer, wherein the first polymer layer contacts a lower portion of the sidewall; and a second polymer layer over and contacting the first polymer layer, wherein the second polymer layer contacts an upper portion of the sidewall. In an embodiment, topmost ends of the first polymer layer are lower than a top surface of the conductive pillar.

In an embodiment, the first polymer layer and the second polymer layer comprise a same polymer material. In an embodiment, the first polymer layer and the second polymer layer comprise different polymer materials. In an embodiment, the first polymer layer comprises a non-planar top surface. In an embodiment, the first polymer layer and the second polymer layer are parts of a device die, and the structure further comprises a molding compound contacting sidewalls of the device die; and a dielectric layer over and contacting both of the second polymer layer and the molding compound. In an embodiment, the structure further comprises a polymer buffer layer comprising a part directly under the second portion of the conductive pillar, wherein the first polymer layer comprises a first part over and contacting the polymer buffer layer; and a second part over and contacting the passivation layer.

In accordance with some embodiments of the present disclosure, a structure comprises a device die comprising a conductive pillar comprising a sidewall; a first polymer layer contacting the sidewall of the conductive pillar; and a second polymer layer over the first polymer layer, wherein the second polymer layer is in contact with the sidewall of the conductive pillar; a gap-fill material encircling the device die, wherein the gap-fill material is in contact with both of the first polymer layer and the second polymer layer; a dielectric layer over and contacting both of the gap-fill material and the second polymer layer; and a redistribution line comprising a portion in the dielectric layer to contact the conductive pillar.

In an embodiment, the second polymer layer fully separates the first polymer layer from the dielectric layer. In an embodiment, the first polymer layer and the second polymer layer comprise different polymer materials.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first conductive pillar over and connecting to a conductive pad;
dispensing a first polymer layer, wherein the first polymer layer contacts a lower portion of a sidewall of the first conductive pillar;
curing the first polymer layer;
dispensing a second polymer layer on the first polymer layer, wherein the second polymer layer contacts an upper portion of the sidewall of the first conductive pillar; and
curing the second polymer layer.

2. The method of claim 1, wherein the dispensing the first polymer layer is performed through spin-on coating.

3. The method of claim 1, wherein the first polymer layer and the second polymer layer comprise a same polymer material.

4. The method of claim 1, wherein the first polymer layer and the second polymer layer comprise different polymer materials.

5. The method of claim 1, wherein the first polymer layer is fully cured before the second polymer layer is dispensed.

6. The method of claim 1, wherein the first polymer layer is partially cured before the second polymer layer is dispensed.

7. The method of claim 1 further comprising, after the second polymer layer is cured, performing a planarization process to level a first top surface of the first conductive pillar with a second top surface of the second polymer layer.

8. The method of claim 1, wherein one of the dispensing the first polymer layer and the dispensing the second polymer layer comprises dispensing polyimide.

9. The method of claim 1 further comprising forming a second conductive pillar, wherein the first polymer layer extends continuously from the first conductive pillar to the second conductive pillar.

10. The method of claim 1 further comprising:
forming a passivation layer comprising a portion on the conductive pad;
depositing a polymer buffer layer on the passivation layer; and
patterning the polymer buffer layer to form an opening, wherein the first conductive pillar comprises a portion in the opening to contact the conductive pad.

11. A structure comprising:
a conductive pad;
a passivation layer partially covering the conductive pad;
a conductive pillar comprising:
a first portion in the passivation layer and in contact with the conductive pad; and
a second portion over the passivation layer, wherein the second portion comprises a sidewall;
a first polymer layer over the passivation layer, wherein the first polymer layer contacts a lower portion of the sidewall; and
a second polymer layer over and contacting the first polymer layer, wherein the second polymer layer contacts an upper portion of the sidewall.

12. The structure of claim 11, wherein topmost ends of the first polymer layer are lower than a top surface of the conductive pillar.

13. The structure of claim 11, wherein the first polymer layer and the second polymer layer comprise a same polymer material.

14. The structure of claim 11, wherein the first polymer layer and the second polymer layer comprise different polymer materials.

15. The structure of claim 11, wherein the first polymer layer comprises a non-planar top surface.

16. The structure of claim 11, wherein the first polymer layer and the second polymer layer are parts of a device die, and the structure further comprises:
a molding compound contacting sidewalls of the device die; and
a dielectric layer over and contacting both of the second polymer layer and the molding compound.

17. The structure of claim 11 further comprising a polymer buffer layer comprising a part directly under the second portion of the conductive pillar, wherein the first polymer layer comprises:
a first part over and contacting the polymer buffer layer; and
a second part over and contacting the passivation layer.

18. A structure comprising:
a device die comprising:
a conductive pillar comprising a sidewall;
a first polymer layer contacting the sidewall of the conductive pillar; and
a second polymer layer over the first polymer layer, wherein the second polymer layer is in contact with the sidewall of the conductive pillar;
a gap-fill material encircling the device die, wherein the gap-fill material is in contact with both of the first polymer layer and the second polymer layer;
a dielectric layer over and contacting both of the gap-fill material and the second polymer layer; and
a redistribution line comprising a portion in the dielectric layer to contact the conductive pillar.

19. The structure of claim 18, wherein the second polymer layer fully separates the first polymer layer from the dielectric layer.

20. The structure of claim 18, wherein the first polymer layer and the second polymer layer comprise different polymer materials.
